(19) United States
(12) Patent Application Publication
(10) Pub. No.: US 2026/0110970 A1
(43) Pub. Date: Apr. 23, 2026

(54) COMPOSITION FOR REMOVING EDGE BEADS FROM METAL-CONTAINING RESISTS, DEVELOPER COMPOSITION OF METAL-CONTAINING RESISTS, AND METHOD OF FORMING PATTERNS USING THE COMPOSITION

(71) Applicant: Samsung SDI Co., Ltd., Yongin-si (KR)

(72) Inventors: Rosa SHIN, Suwon-si (KR); Hyungrang MOON, Suwon-si (KR); Seung HAN, Suwon-si (KR); Taeho KIM, Suwon-si (KR); Si-Kyun PARK, Suwon-si (KR); Taeksoo KWAK, Suwon-si (KR); Gyeonghun PARK, Suwon-si (KR)

(21) Appl. No.: 19/354,753

(22) Filed: Oct. 9, 2025

(30) Foreign Application Priority Data
Oct. 18, 2024 (KR) 10-2024-0143302

(51) Int. Cl. G03F 7/16; G03F 7/004

(52) U.S. Cl. CPC G03F 7/168; G03F 7/0042

(57) ABSTRACT

A composition to remove edge beads from a metal-containing resist or a developer composition of a metal-containing resist and a method of forming or providing patterns utilizing the composition or the developer composition are disclosed. The composition to remove edge beads from the metal-containing resist or the developer composition of the metal-containing resist may include a cyclic compound including at least one heteroatom selected from among N, O, and S in a ring and at least two carbonyl groups; and a solvent.

### CROSS-REFERENCE TO RELATED APPLICATION

The present application claims priority to and the benefit of Korean Patent Application No. 10-2024-0143302, filed on Oct. 18, 2024, in the Korean Intellectual Property Office, the entire disclosure of which is incorporated herein by reference.

### BACKGROUND

### 1. Field

One or more embodiments of the present disclosure relate to a composition to remove edge beads from a metal-containing resist or a developer composition of a metal-containing resist and a method of forming or providing patterns utilizing the composition or the developer composition.

### 2. Description of the Related Art

The semiconductor industry has undergone a continuous reduction of critical dimensions, and, for this dimensional reduction, it is desirable to develop new types or kinds of high-performance photoresist materials and a patterning method that is suitable for processing and patterning with increasingly smaller features.

With the development of the semiconductor industry, a semiconductor device is required or desired to have a fast operating speed and large storage capacity, and in line with this requirement, process technology to improve or enhance integration, reliability, and a response speed of the semiconductor device is being developed. For example, it is important or desirable to accurately control/implant impurities in working regions of a silicon substrate and to interconnect these regions to form or provide a device and an ultra-high-density integrated circuit, which may be achieved by a photolithographic process. For example, it is important or desirable to integrate the photolithographic process including coating a photoresist on the substrate, selectively exposing it to ultraviolet (UV) (including extreme ultraviolet (EUV)), electron beams, X rays, and/or the like, and then, developing it.

For example, in the process of forming or providing the photoresist layer, the resist is coated on the substrate, mainly or predominantly while rotating the silicon substrate, wherein the resist is coated on an edge and rear surface of the substrate, which may cause particles or pattern defects in the subsequent semiconductor processes, such as etching and ion implantation processes. Accordingly, a process to strip and remove the photoresist coated on the edge and rear surface of the silicon substrate by utilizing a thinner composition, for example, an edge bead removal (EBR) process is performed. The EBR process requires a composition that exhibits excellent or suitable solubility for the photoresist and effectively or suitably removes beads and the photoresist remaining in the substrate and generates no resist residue.

It is desirable to develop a photoresist that can ensure excellent or suitable etch resistance and resolution in the photolithography process, while improving or enhancing sensitivity and critical dimension (CD) uniformity (e.g., substantial uniformity) and can improve line edge roughness (LER) characteristics, and a developer composition that can implement it.

### SUMMARY

One or more aspects of embodiments of the present disclosure are directed toward a composition to remove edge beads from a metal-containing resist or a developer composition of a metal-containing resist.

One or more aspects of embodiments of the present disclosure are directed toward a composition including: a cyclic compound including at least one heteroatom selected from among nitrogen (N), oxygen (O), and sulfur (S) in a ring and at least two carbonyl groups; and a solvent, wherein the composition is a composition to remove edge beads from a metal-containing resist or a developer composition of a metal-containing resist.

One or more aspects of embodiments of the present disclosure are directed toward a method of forming or providing patterns utilizing the compositions (e.g., the composition to remove edge beads from the metal-containing resist and/or the developer composition of the metal-containing resist).

Additional aspects of embodiments will be set forth in part in the description which follows and, in part, will be apparent from the description or may be learned by practice of the presented embodiments of the disclosure.

A composition to remove edge beads from a metal-containing resist or a developer composition of a metal-containing resist according to one or more embodiments includes: a cyclic compound including at least one heteroatom selected from among nitrogen (N), oxygen (O), and sulfur (S) in a ring and at least two carbonyl groups; and a solvent.

A method of forming or providing patterns according to one or more embodiments includes coating a metal-containing resist composition on a substrate; coating the composition to remove edge beads from the metal-containing resist as described in one or more embodiments along an edge of the substrate; performing heat treatment to form or provide a metal-containing photoresist film on the substrate by drying and heating; exposing the metal-containing photoresist film; and developing.

A method of forming or providing patterns according to one or more embodiments includes coating a metal-containing resist composition on a substrate; performing heat treatment to form or provide a metal-containing photoresist film on the substrate by drying and heating; exposing the metal-containing photoresist film; and developing utilizing the developer composition of the metal-containing resist as described in one or more embodiments.

A method of forming or providing patterns according to one or more embodiments includes coating a metal-containing resist composition on a substrate; coating the composition to remove edge beads from the metal-containing resist as described in one or more embodiments along an edge of the substrate; performing heat treatment to form or provide a metal-containing photoresist film on the substrate by drying and heating; exposing the metal-containing photoresist film; and developing utilizing the developer composition of the metal-containing resist as described in one or more embodiments.

The composition to remove edge beads from the metal-containing resist according to one or more embodiments may reduce the metal-based contamination inherent in the metal-containing resist and remove the resist coated on the edge and the rear surface of the substrate, thereby satisfying the requirements of processing and patterning of smaller features.

The developer composition of the metal-containing resist according to one or more embodiments may enable excellent or suitable contrast characteristics, excellent or suitable sensitivity, and reduced line edge roughness (LER) to be realized by minimizing defects (or reducing a degree or occurrence of defects) present in a metal-containing photoresist film after an exposure process and facilitating development.

### BRIEF DESCRIPTION OF THE DRAWINGS

The above and other aspects and features of certain embodiments of the present disclosure will become more apparent from the following description taken in conjunction with the accompanying drawings.

FIG. 1 is a schematic view of a photoresist coating apparatus.

FIGS. 2A-2C are a cross-sectional view illustrated according to the process sequence to describe a method of forming or providing patterns.

### DETAILED DESCRIPTION

Hereinafter, the subject matter of the present disclosure are described in more detail with reference to the accompanying drawings. In the following description of the present disclosure, the functions or constructions that are generally understood by a person of ordinary skill in the art may not be described in order to clarify the present disclosure.

The utilization of “may” if (e.g., when) describing embodiments of the present disclosure refers to “one or more embodiments of the present disclosure.”

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, 20%, 10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

In order to clearly illustrate the present disclosure, the description and relationships may not be provided, and throughout the disclosure, substantially the same or similar configuration or arrangement elements may be designated by the same reference numerals. Also, because the size and thickness of each configuration or arrangement illustrated in the drawing may be arbitrarily shown for better understanding and ease of description, embodiments of the present disclosure are not necessarily limited thereto.

In the drawings, the thickness of layers, films, panels, regions, and/or the like may be exaggerated for clarity. In the drawings, the thickness of a part of layers, regions, and/or the like may be exaggerated for better understanding and ease of description.

It will be understood that if (e.g., when) an element, such as a layer, a film, a region, or a substrate, is referred to as being “on” or “above” another element, it may be directly on the other element or intervening elements may also be present therebetween. In contrast, if (e.g., when) an element is referred to as being “directly on” or “directly above” another element, there are no intervening elements present therebetween.

In the present disclosure, “substituted” refers to replacement of a hydrogen atom by deuterium, a halogen, a hydroxyl group, a thiol group, a cyano group, a carbonyl group, a carboxyl group, an amino group, an amide group, an ester group, a substituted or unsubstituted C1 to C30 amine group, a nitro group, a substituted or unsubstituted C1 to C40 silyl group, a substituted or unsubstituted C1 to C30 alkyl group, a substituted or unsubstituted C1 to C10 haloalkyl group, a substituted or unsubstituted C1 to C10 alkylsilyl group, a substituted or unsubstituted C3 to C30 cycloalkyl group, a substituted or unsubstituted C6 to C30 aryl group, a substituted or unsubstituted C1 to C20 alkoxy group, or a substituted or unsubstituted C1 to C20 sulfide group. “Unsubstituted” refers to that a hydrogen atom remains as a hydrogen atom without being replaced by another substituent.

In the present disclosure, “alkyl group” refers to a linear or branched aliphatic hydrocarbon group, unless otherwise defined. The alkyl group may be a “saturated alkyl group” that does not contain any double bond (e.g., a carbon-carbon double bond) or a triple bond (a carbon-carbon triple bond).

The alkyl group may be a C1 to C20 alkyl group. For example, the alkyl group may be a C1 to C10 alkyl group or a C1 to C6 alkyl group. For example, a C1 to C5 alkyl group refers to that the alkyl chain contains 1 to 5 carbon atoms and may be selected from among methyl, ethyl, propyl, iso-propyl, n-butyl, iso-butyl, sec-butyl, and t-butyl.

Examples of the alkyl group may include a methyl group, an ethyl group, a propyl group, an isopropyl group, a butyl group, an isobutyl group, a tert-butyl group, a pentyl group, a hexyl group, and/or the like.

In the chemical formulas as described herein, t-Bu refers to a tert-butyl group.

In the present disclosure, “aryl group” refers to a substituent in which all elements of a cyclic substituent have p-orbitals, and these p-orbitals form a conjugate and may include monocyclic or fused ring polycyclic (e.g., rings that share adjacent pairs of carbon atoms) functional groups.

Examples of the aryl group may include a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted benzophenanthrenyl group, a substituted or unsubstituted triphenylene group, a substituted or unsubstituted perylenyl group, a substituted or unsubstituted fluorenyl group, a substituted or unsubstituted indenyl group, or a combination thereof, but embodiments of the present disclosure are not limited thereto.

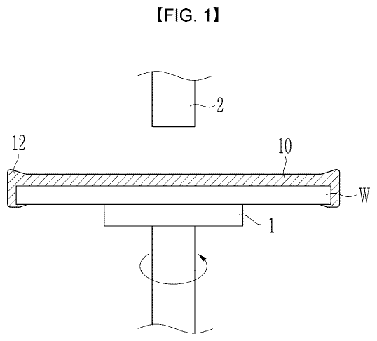

FIG. 1 is a schematic view illustrating the photoresist coating apparatus.

Referring to FIG. 1, a substrate support portion 1 on which a substrate W is placed may be equipped therewith, and the substrate support portion 1 may include a spin chuck and/or a spin coater.

The substrate support portion 1 may rotate in a first direction at a set or predetermined rotation speed to provide a centrifugal force to the substrate W. A spray nozzle 2 may be disposed or provided on the substrate support portion 1, and the spray nozzle 2 may be disposed or provided in an air region away from the upper portion of the substrate W and may move to the upper portion of the substrate during the solution supply stage to spray the photoresist solution 10. Accordingly, the photoresist solution 10 may be coated on the surface of the substrate W by the centrifugal force. Herein, the photoresist solution 10 supplied to the center of the substrate W may be coated while spreading to the edge of the substrate W by the centrifugal force, wherein a portion of photoresist solution 10 moves to the side surfaces of the substrate W and the lower surface of the edge of the substrate.

For example, in the coating process, the photoresist solution 10 may be coated mainly or predominantly in a spin coating method, wherein a set or predetermined amount of the photoresist solution 10 having viscosity is supplied to the center portion of the substrate W and gradually spreads toward the edge of the substrate W by the centrifugal force.

Accordingly, the photoresist may be evenly (e.g., substantially evenly) formed or provided by a rotational speed of the substrate support portion.

In one or more embodiments, this rotation may evaporate a solvent from the solution and thereby gradually increases the viscosity, resulting in making a relatively large amount of the photoresist accumulated on the edge of the substrate by the action of surface tension and severely or substantially even onto the lower surface of the edge of the substrate, which is referred to as edge beads 12.

Hereinafter, a composition to remove edge beads from a metal-containing resist or a developer composition of a metal-containing resist according to one or more embodiments are described in more detail.

The composition to remove edge beads from a metal-containing resist or a developer composition of a metal-containing resist according to one or more embodiments may include a cyclic compound including at least one heteroatom selected from among N, O, and S in a ring and at least two carbonyl groups; and a solvent.

Because the cyclic compound as described in one or more embodiments allows free movement of delocalized electrons through conjugation of a carbonyl group with at least one heteroatom selected from among N, O, and S in the structure, it may be advantageous or beneficial to form hydrogen bonds with the side ligands of the metal-containing resist by including the cyclic compound and have the effect of inducing desorption of the ligand. Accordingly, the cyclic compound may bind to a metal and effectively or suitably remove the metal-containing resist, for example, metal residues, such as tin-based metal residues, thereby improving or enhancing pattern-forming capability.

For example, the cyclic compound may be represented by any one selected from among Chemical Formula 1 to Chemical Formula 3.

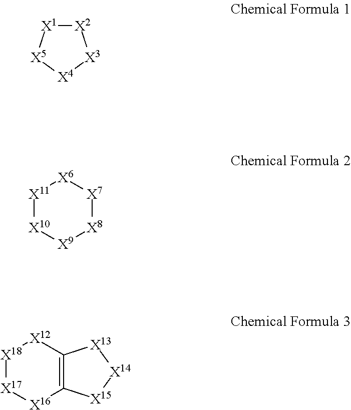

In Chemical Formula 1 to Chemical Formula 3,
X¹ to X¹⁸ may each independently be a carbonyl group (C═(O)), CR¹R², NR³, O, or S,
at least one selected from among X¹ to X⁵ may be NR³, O, or S, and at least two may be carbonyl groups,
at least one selected from among X⁶ to X¹¹ may be NR³, O, or S and at least two may be carbonyl groups,
at least one selected from among X¹² to X¹⁸ may be NR³, O, or S and at least two may be carbonyl groups, and
R¹ to R³ may each independently be hydrogen, a hydroxyl group, a substituted or unsubstituted C1 to C10 alkyl group, or a combination thereof.

For example, Chemical Formula 1 may be represented by Chemical Formula 1-1.

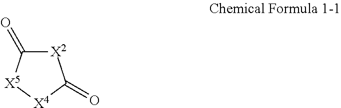

In Chemical Formula 1-1,
X², X⁴, and X⁵ may each independently be CR¹R², NR³, O, or S,
at least one selected from among X², X⁴, and X⁵ may be NR³, O, or S, and
R¹ to R³ may each independently be hydrogen, a hydroxyl group, a substituted or unsubstituted C1 to C10 alkyl group, or a combination thereof.

For example, at least one selected from X⁴ and X⁵ may be NR³, O, or S.

For example, X⁴ and X⁵ may each independently be NR³, O, or S.

For example, Chemical Formula 2 may be represented by one of Chemical Formula 2-1 to Chemical Formula 2-3.

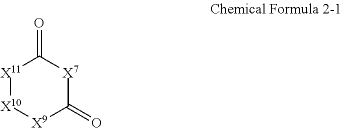

In Chemical Formula 2-1,
X⁷, X⁹, X¹⁰, and X¹¹ may each independently be CR¹R², NR³, O, or S,
at least one selected from among X⁷, X⁹, X¹⁰, and X¹¹ may be NR³, O, or S, and
R¹ to R³ may each independently be hydrogen, a hydroxyl group, a substituted or unsubstituted C1 to C10 alkyl group, or a combination thereof.

For example, at least one selected from among X⁷, X⁹, and X¹¹ may be NR³, O, or S.

For example, at least one selected from X⁷ and X¹¹ may be NR³, O, or S.

For example, at least one selected from X⁹ and X¹¹ may be NR³, O, or S.

For example, X⁷ and X⁹ may each independently be NR³, O, or S.

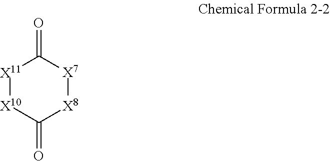

In Chemical Formula 2-2,
X⁷, X⁸, X¹⁰, and X¹¹ may each independently be CR¹R², NR³, O, or S,
at least one selected from among X⁷, X⁸, X¹⁰, and X¹¹ may be NR³, O, or S, and
R¹ to R³ may each independently be hydrogen, a hydroxyl group, a substituted or unsubstituted C1 to C10 alkyl group, or a combination thereof.

For example, at least one selected from among X⁷, X⁸, and X¹⁰ may be NR³, O, or S.

For example, at least one selected from X⁷ and X¹⁰ may be NR³, O, or S.

For example, at least one selected from X⁷ and X¹⁰ may each independently be NR³, O, or S.

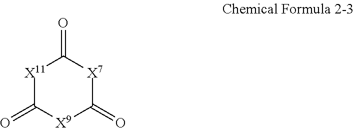

In Chemical Formula 2-3,
X⁷, X⁹, and X¹¹ may each independently be CR¹R², NR³, O, or S,
at least one selected from among X⁷, X⁹, and X¹¹ may be NR³, O, or S,
R¹ to R³ may each independently be hydrogen, a hydroxyl group, a substituted or unsubstituted C1 to C10 alkyl group, or a combination thereof.

For example, X⁷ and X¹¹ may each independently be NR³, O, or S.

For example, X⁷, X⁹, and X¹¹ may each independently be NR³, O, or S.

For example, Chemical Formula 3 may be represented by one selected from among Chemical Formula 3-1 to Chemical Formula 3-3.

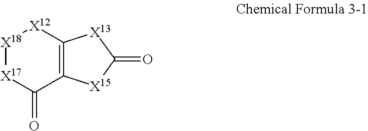

In Chemical Formula 3-1,
X¹², X¹³, X¹⁵, X¹⁷, and X¹⁸ may each independently be CR¹R², NR³, O, or S,
at least one selected from among X¹², X¹³, X¹⁵, X¹⁷, and X¹⁸ may be NR³, O, or S, and
R¹ to R³ may each independently be hydrogen, a hydroxyl group, a substituted or unsubstituted C1 to C10 alkyl group, or a combination thereof.

For example, at least two selected from among X¹², X¹³, X¹⁵, X¹⁷, and X¹⁸ may each independently be NR³, O, or S.

For example, at least three selected from among X¹², X¹³, X¹⁵, X¹⁷, and X¹⁸ may each independently be NR³, O, or S.

For example, at least four selected from among X¹², X¹³, X¹⁵, X¹⁷, and X¹⁸ may each independently be NR³, O, or S.

For example, X¹², X¹³, X¹⁵, and X¹⁷ may each independently be NR³, O, or S.

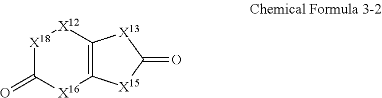

In Chemical Formula 3-2,
X¹², X¹³, X¹⁵, X¹⁶, and X¹⁸ may each independently be CR¹R², NR³, O, or S,
at least one selected from among X¹², X¹³, X¹⁵, X¹⁶, and X¹⁸ may be NR³, O, or S, and
R¹ to R³ may each independently be hydrogen, a hydroxyl group, a substituted or unsubstituted C1 to C10 alkyl group, or a combination thereof.

For example, two selected from among X¹², X¹³, X¹⁵, X¹⁶, and X¹⁸ may each independently be NR³, O, or S.

For example, three selected from among X¹², X¹³, X¹⁵, X¹⁶, and X¹⁸ may each independently be NR³, O, or S.

For example, four selected from among X¹², X¹³, X¹⁵, X¹⁶, and X¹⁸ may each independently be NR³, O, or S.

For example, X¹³, X¹⁵, X¹⁶, and X¹⁸ may each independently be NR³, O, or S.

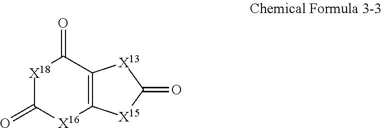

In Chemical Formula 3-3,
X¹³, X¹⁵, X¹⁶, and X¹⁸ may each independently be CR¹R², NR³, O, or S,
at least one selected from among X¹³, X¹⁵, X¹⁶, and X¹⁸ may be NR³, O, or S, and
R¹ to R³ may each independently be hydrogen, a hydroxyl group, a substituted or unsubstituted C1 to C10 alkyl group, or a combination thereof.

For example, two selected from among X¹³, X¹⁵, X¹⁶, and X¹⁸ may each independently be NR³, O, or S.

For example, three selected from among X¹³, X¹⁵, X¹⁶, and X¹⁸ may each independently be NR³, O, or S.

For example, X¹³, X¹⁵, X¹⁶, and X¹⁸ may each independently be NR³, O, or S.

In one or more embodiments, the cyclic compound may be at least one selected from among the compounds listed in Group 1.

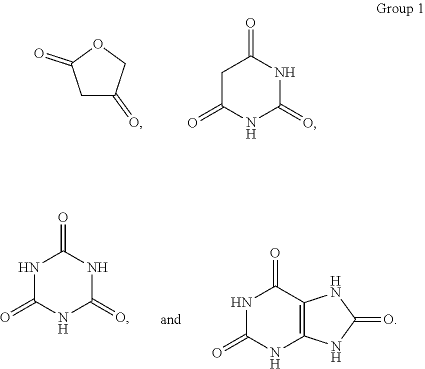 [SMILES: O=C1COC(=O)C1 ; O=C1CC(=O)NC(=O)N1 ; O=c1[nH]c(=O)[nH]c(=O)[nH]1 ; O=c1[nH]c(=O)c2[nH]c(=O)[nH]c2[nH]1]

In one or more embodiments, the cyclic compound may be in an amount of about 0.1 wt % to about 50 wt % based on the total weight (e.g., based on 100 wt %) of the composition (e.g., the composition to remove edge beads from the metal-containing resist or the developer composition of the metal-containing resist).

For example, the cyclic compound may be in an amount of about 0.1 wt % to about 40 wt % or about 0.5 wt % to about 40 wt % based on the total weight (e.g., based on 100 wt %) of the composition (e.g., the composition to remove edge beads from the metal-containing resist or the developer composition of the metal-containing resist).

Examples of the solvent in the composition to remove edge beads from the metal-containing resist or the developer composition according to one or more embodiments may include deionized water (DIW), propylene glycol methyl ether (PGME), propylene glycol methyl ether acetate (PGMEA), propylene glycol butyl ether (PGBE), ethylene glycol methyl ether, diethyl glycol ethyl methyl ether, dipropyl glycol dimethyl ether, ethanol, 2-butoxyethanol, n-propanol, isopropanol, n-butanol, isobutanol, hexanol, ethylene glycol, propylene glycol, heptanone, propylene carbonate, butylene carbonate, diethyl ether, dibutyl ether, ethyl acetate, methyl 3-methoxypropionate, ethyl 3-ethoxypropionate, diisopentyl ether, xylene, acetone, methylethylketone, methyl isobutyl ketone, tetrahydrofuran, dimethyl sulfoxide, dimethyl formamide, acetonitrile, diacetone alcohol, 3,3-dimethyl-2-butanone, N-methyl-2-pyrrolidone, dimethyl acetamide, cyclohexanone methyl-2-hydroxy-2-methylpropanate (HBM), gamma butyrolactone (GBL), 1-butanol (n-butanol), ethyl lactate (EL), diene butyl ether (DBE), diisopropyl ether (DIAE), acetyl acetone, butyl actate (n-butyl actate), 4-methyl-2-pentanol (also may be described as methyl isobutyl carbinol (MIBC)), 1-methoxy-2-propanol, 1-ethoxy-2-propanol, toluene, xylene, methylethylketone, cyclopentanone, cyclohexanone, 2-hydroxyethyl propionate, 2-hydroxy-2-methylethyl propionate, ethyl ethoxyacetate, ethyl hydroxyacetate, methyl 2-hydroxy-3-methylbutanoate, 3-methoxymethyl propionate, 3-methoxyethyl propionate, 3-ethoxyethyl propionate, 3-ethoxymethyl propionate, methyl pyruvate, ethyl pyruvate, ethyl acetate, butyl acetate, ethyl lactate, butyl lactate, methyl 2-hydroxyisobutyrate, methoxybenzene, n-butyl acetate, 1-methoxy-2-propyl acetate, methyl methoxypropionate, ethyl ethoxypropionate, or a mixture thereof, but embodiments of the present disclosure are not limited thereto.

The composition to remove edge beads from the metal-containing resist according to one or more embodiments may be effective or suitable in removing metal-containing resist, for example, undesirable metal residues, such as tin-based metal residues.

In one or more embodiments, the developer composition of the metal-containing resist according to the present disclosure may minimize defects (or reduce a degree or occurrence of defects) in the metal-containing photoresist film after the exposure process and may allow for easy development, thereby realizing excellent or suitable pattern characteristics.

In one or more embodiments, excellent or suitable sensitivity and reduced line edge roughness (LER) may be achieved.

In the case of including other additives to be described herein in more detail, the solvent may be in a balance amount excluding the included components.

It may further include at least one other additive selected from among a surfactant, a dispersant, a moisture absorbent, and a coupling agent.

The metal compound in the metal-containing resist may be an organotin compound including at least one selected from an organic oxy group and an organic carbonyloxy group.

For example, the metal compound in the metal-containing resist may be represented by Chemical Formula 4.

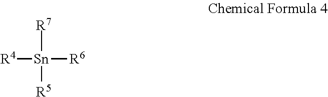

In Chemical Formula 4,
R⁴ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R⁵ to R⁷ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, an alkoxy or aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h})Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein Rⁱ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R⁵ to R⁷ may be selected from an alkoxy or aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h})Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein Rⁱ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

As another example, the metal compound in the metal-containing resist may be represented by Chemical Formula 5 or Chemical Formula 6.

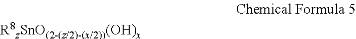

In Chemical Formula 5,
R⁸ may be a C1 to C31 hydrocarbyl group, 0<z≤2, and 0<(z+x)≤4;

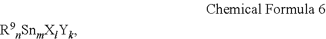

wherein, in Chemical Formula 6,
R⁹ may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds (e.g., a carbon-carbon double bond) or triple bonds (e.g., a carbon-carbon triple bond), a substituted or unsubstituted C6 to C30 aryl group, a substituted or unsubstituted C4 to C30 heteroaryl group, a carbonyl group, an ethylene oxide group, a propylene oxide group, or a combination thereof,
X may be sulfur (S), selenium (Se), or tellurium (Te),
Y may be —OR^{m} or —OC(═O)Rⁿ,
wherein R^{m} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
n, m, l, and k may each independently be an integer of 1 to 20.

According to one or more embodiments, a method of forming or providing patterns may include removing the edge beads utilizing the composition as described in one or more embodiments. For example, the manufactured pattern may be a photoresist pattern. For example, it may be a negative-type or kind photoresist pattern.

A method of forming or providing patterns according to one or more embodiments may include coating a metal-containing resist composition on a substrate, coating the composition to remove edge beads from the metal-containing resist as described in one or more embodiments along an edge of the substrate, performing heat treatment to form or provide a metal-containing photoresist film on the substrate by drying and heating, exposing the metal-containing photoresist film, and developing.

For example, the forming or providing of patterns utilizing the metal-containing resist composition may include coating a metal-containing resist composition on a substrate on which a thin film is formed or provided by spin coating, slit coating, inkjet printing, and/or the like, and drying the coated metal-containing resist composition to form or provide a photoresist film. The metal-containing resist composition may include a tin-based compound, and for example, the tin-based compound may include at least one selected from an organic oxy group-containing tin compound and an organic carbonyloxy group-containing tin compound.

For example, the edge beads of the metal-containing resist may be removed by coating an appropriate or suitable amount of the composition to remove an edge beads of the metal-containing resist along the edge of the substrate while rotating the substrate at an appropriate or suitable speed (e.g., 500 rpm or more).

Subsequently, a first heat treatment process of heating the substrate on which the photoresist film is formed or provided may be performed. The first heat treatment process may be performed at a temperature of about 80° C. to about 120° C., and in this process, the solvent may be evaporated and the photoresist film may be more firmly or suitably adhered to the substrate.

Then, the photoresist film may be selectively exposed.

Examples of light that may be used in the exposure process may include not only light having relatively low energy wavelengths, such as i-line (wavelength of 365 nm), KrF excimer laser (wavelength of 248 nm), ArF excimer laser (wavelength of 193 nm), and/or the like, but also light having relatively high energy wavelengths, such as extreme ultraviolet (EUV; wavelength of 13.5 nm) and/or the like, but also other sources, such as an electron beam (e-beam) and/or the like.

For example, the light for exposure according to one or more embodiments may be light having a wavelength range of about 5 nm to about 150 nm, and light having relatively high energy wavelengths, such as extreme ultraviolet (EUV; wavelength of 13.5 nm), and other sources, such as an electron beam (e-beam) and/or the like.

In the forming or providing of the photoresist pattern, a negative-type or kind pattern may be formed or provided.

The exposed region of the photoresist film may have a solubility different from a solubility of the unexposed region of the photoresist film as a polymer is formed or provided by a crosslinking reaction, such as condensation between organometallic compounds.

Then, a second heat treatment process may be performed on the substrate. The second heat treatment process may be performed at a temperature of about 90° C. to about 200° C. By performing the second heat treatment process, the exposed region of the resist film may become difficult to be dissolved in a developer.

For example, the photoresist pattern corresponding to the negative tone image may be completed by dissolving and removing the photoresist film corresponding to the unexposed region utilizing a solvent, such as 2-heptanone.

Examples of the solvent in the developer composition utilized in the method of forming or providing patterns according to one or more embodiments may include ketones, such as methyl ethyl ketone, acetone, cyclohexanone, and/or 2-heptanone, alcohols, such as 4-methyl-2-propanol, 1-butanol, isopropanol, 1-propanol, and/or methanol, esters, such as propylene glycol monomethyl ether acetate, ethyl acetate, ethyl lactate, n-butyl acetate, and/or butyrolactone, aromatic compounds, such as benzene, xylene, and/or toluene, or a combination thereof.

As described in one or more embodiments, the photoresist pattern formed or provided by exposure to not only light having relatively low energy wavelengths, such as i-line (wavelength of 365 nm), KrF excimer laser (wavelength of 248 nm), ArF excimer laser (wavelength of 193 nm), and/or the like, but also light having relatively high energy wavelengths, such as extreme ultraviolet (EUV; wavelength of 13.5 nm) and/or the like, but also other sources, such as an electron beam (e-beam) and/or the like, may have a thickness width of about 5 nm to about 100 nm. For example, the photoresist pattern may be formed or provided to have a thickness width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In one or more embodiments, the photoresist pattern may have a pitch having a half-pitch of less than or equal to about 50 nm, for example, less than or equal to 40 nm, for example, less than or equal to 30 nm, for example, less than or equal to 20 nm, for example, less than or equal to 15 nm, and a line width roughness of less than or equal to about 10 nm, less than or equal to about 5 nm, less than or equal to about 3 nm, or less than or equal to about 2 nm.

A method of forming or providing patterns according to one or more embodiments may include coating a metal-containing resist composition on a substrate, performing heat treatment to form or provide a metal-containing photoresist film on the substrate by drying and heating, exposing the metal-containing photoresist film, and developing utilizing the composition as described in one or more embodiments.

The coating of the metal-containing resist composition on a substrate may be substantially the same as described in one or more embodiments.

The heat treatment of drying and heating to form or provide a metal-containing photoresist film on the substrate may be substantially the same as described in one or more embodiments.

The exposing of the metal-containing photoresist film may be substantially the same as described in one or more embodiments.

The photoresist pattern corresponding to the negative tone image may be completed by dissolving the photoresist film corresponding to the unexposed region utilizing the developer composition of the metal-containing resist as described in one or more embodiments and then removing the photoresist film.

Examples of the metal compound in the metal-containing resist composition may be substantially the same as described in one or more embodiments.

Hereinafter, a method of forming or providing patterns by development is described in more detail with reference to the drawings.

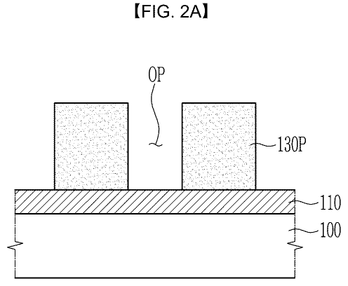

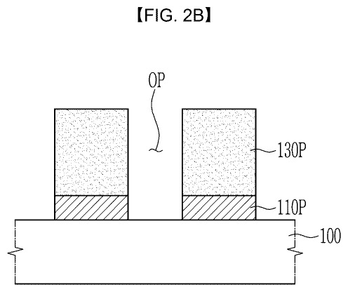

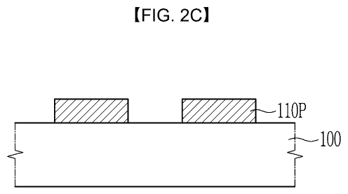

FIGS. 2A-2C are cross-sectional views illustrating a process sequence in order to describe a method of forming or providing patterns.

Referring to FIG. 2A, the exposed photoresist film may be developed to form or provide a photoresist pattern 130P.

In one or more embodiments, the exposed photoresist film may be developed to remove an unexposed region of the photoresist film, and the photoresist pattern 130P including the exposed region of the photoresist film may be formed or provided. The photoresist pattern 130P may include a plurality of openings OP.

In one or more embodiments, the development of the photoresist film may be performed through a negative-tone development (NTD) process. Herein, the metal-containing photoresist developer composition according to one or more embodiments may be utilized as a developer composition.

Referring to FIG. 2B, the photoresist pattern 130P may be utilized to process a feature layer 110 in the result of FIG. 2A.

For example, the feature layer 110 may be processed through one or more suitable processes of etching a feature layer 110 exposed through the openings OP of the photoresist pattern 130P, injecting impurity ions into the feature layer 110, forming or providing an additional film on the feature layer 110 through the openings OP, deforming a portion of the feature layer 110 through the openings OP, and/or the like. FIG. 2B illustrates a process to process a feature pattern 110P by etching the feature layer 110 exposed through the openings OP.

Referring to FIG. 2C, the photoresist pattern 130P remaining on the feature pattern 110P may be removed in the result of FIG. 2B. In order to remove the photoresist pattern 130P, an ashing and stripping process may be used. The feature pattern 110P is on a substrate 100.

A method of forming or providing patterns according to one or more embodiments may include coating a metal-containing resist composition on a substrate, coating the composition to remove edge beads from the metal-containing resist as described in one or more embodiments along an edge of the substrate, performing heat treatment to form or provide a metal-containing photoresist film on the substrate by drying and heating, exposing the metal-containing photoresist film, and developing utilizing the developer composition of the metal-containing resist as described in one or more embodiments.

Each method may be substantially the same as described in one or more embodiments, but in the removing method of edge beads and the developing method, the composition to remove edge beads from the metal-containing resist or the developer composition of the metal-containing resist according to the present disclosure may be concurrently (e.g., simultaneously) utilized to effectively or suitably improve or enhance an effect of removing the edge beads and solubility of the unexposed region and thus satisfying the needs to process and pattern smaller features, resultantly realizing excellent or suitable contrast characteristics, excellent or suitable sensitivity, and reduced line edge roughness (LER).

Hereinafter, the subject matter of the present disclosure will be described in more detail through examples of the preparation of the composition to remove edge beads from the metal-containing resist as described in one or more embodiments and the developer composition of the metal-containing resist as described in one or more embodiments. However, embodiments of the present disclosure are not limited by the following examples.

Preparation of Composition to Remove Edge Beads from Metal-Containing Resist

### Example 1

The cyclic compound and solvent were mixed according to the compositions in Table 1, then stirred at room temperature (25° C.) to completely (e.g., substantially completely) dissolve. Then, the final composition was obtained by passing it through a polytetrafluoroethylene (PTFE) material filter having a pore size of 1 μm.

### Examples 2 to 5 and Comparative Examples 1 to 5

Each composition was obtained in substantially the same manner as in Example 1 except that the composition was changed into each composition shown in Table 1.

TABLE 1

Composition to remove edge beads
from a metal-containing resist

| | Cyclic compound (wt %) | | Solvent (wt %) |
|---|---|---|---|
| Example 1 | A1 | (40) | EL/DIW (9/1) (60) |
| Example 2 | A2 | (40) | EL (60) |
| Example 3 | A2 | (5) | EL (95) |
| Example 4 | A3 | (40) | EL (60) |
| Example 5 | A4 | (40) | EL/DIW (9/1) (60) |
| Comparative | A6 | (40) | EL (60) |
| Example 1 | | | |
| Comparative | A7 | (40) | EL (60) |
| Example 2 | | | |
| Comparative | A8 | (30) | EL (60) |
| Example 3 | | | |
| Comparative | A9 | (40) | EL (60) |
| Example 4 | | | |
| Comparative | A10 | (40) | EL (60) |
| Example 5 | | | |

The solvent mixing ratio in Table 1 is the weight ratio.

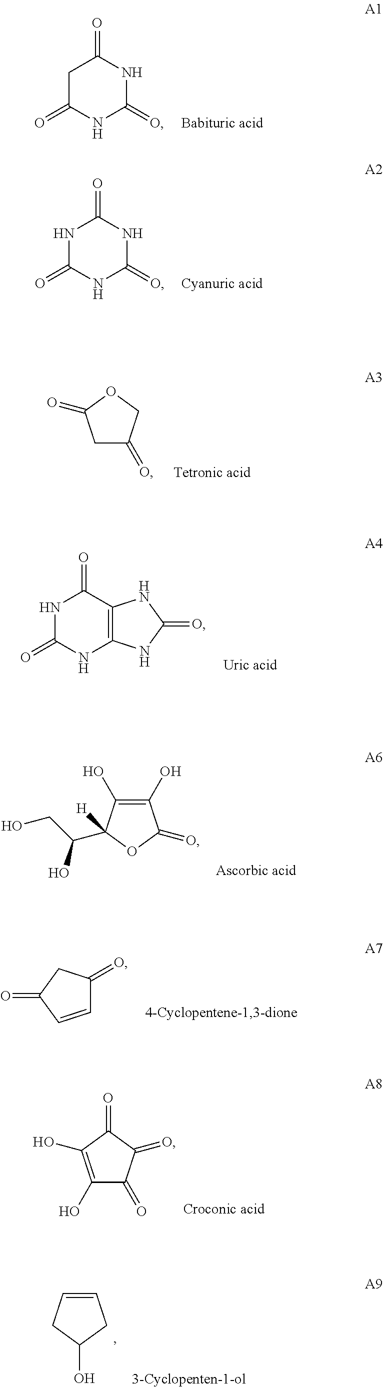

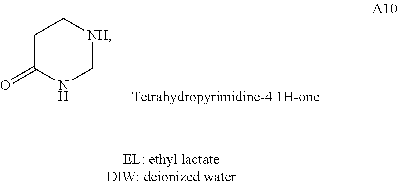

### Preparation of Developer Composition of Metal-Containing Resist

### Example 7

The cyclic compound and solvent were mixed according to the compositions in Table 2, then stirred at room temperature (25° C.) to completely (e.g., substantially completely) dissolve. Then, the final composition was obtained by passing it through a PTFE material filter having a pore size of 1 μm.

### Examples 8 to 11 and Comparative Examples 6 to 10

Each composition was obtained in substantially the same manner as in Example 7 except that the composition was changed into each composition shown in Table 2.

TABLE 2

| | Developer composition of a metal-containing resist | | | |
|---|---|---|---|---|
| | Cyclic compound (wt %) | | Solvent (wt %) | |
| Example 7 | A1 | (5) | EL/DIW (9/1) (95) | |
| Example 8 | A2 | (5) | EL | (95) |
| Example 9 | A2 | (0.5) | EL | (99.5) |
| Example 10 | A3 | (5) | EL | (95) |
| Example 11 | A4 | (5) | EL/DIW (9/1) (95) | |
| Comparative | A6 | (5) | EL | (95) |
| Example 6 | | | | |
| Comparative | A7 | (5) | EL | (95) |
| Example 7 | | | | |
| Comparative | A8 | (5) | EL | (95) |
| Example 8 | | | | |
| Comparative | A9 | (5) | EL | (95) |
| Example 9 | | | | |
| Comparative | A10 | (5) | EL | (95) |
| Example 10 | | | | |

The solvent mixing ratio in Table 2 is the weight ratio.

### Preparation of Organometal-Containing Photoresist Composition

### Preparation Example

An organometallic compound (weight average molecular weight: 1,500 g/mol) having the structural unit of Chemical Formula C was dissolved in 4-methyl-2-pentanol at a concentration of 1 wt %, then filtered through a 0.1 μm PTFE syringe filter to prepare a photoresist composition.

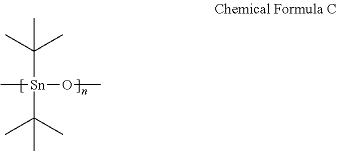

### Evaluation 1: Evaluation of Sn Residual Amount

1.0 mL of the photoresist composition including an organometallic compound according to Preparation Example was poured onto a 6-inch silicon wafer, allowed to stand for 20 seconds, and then spin-coated at a speed of 800 rpm for 30 seconds. Then, the resist film obtained by heat treatment at 200° C. for 60 seconds was subjected to thickness measurement using the ellipsometry method. On a wafer having a resist film formed or provided thereon, 10 mL of each of the compositions to remove edge beads of Examples 1 to 7 and Comparative Examples 1 to 12 according to Table 1 was injected along the edge, spin-coated for 5 seconds, and then dried while rotating at a speed of 1,500 rpm. Then, vapor phase decomposition-inductively coupled plasma mass spectrometry (VPD ICP-MS) analysis was performed on the film obtained by heat treatment at 150° C. for 60 seconds to confirm the Sn residual amount, and the results are shown in Table 3.

TABLE 3

| | Sn residual amount (×10¹⁰ atoms/cm²) |
|---|---|
| Example 1 | 3,400 |
| Example 2 | 2,200 |
| Example 3 | 4,300 |
| Example 4 | 4,800 |
| Example 5 | 6,100 |
| Comparative Example 1 | 9,200 |
| Comparative Example 2 | 12,100 |
| Comparative Example 3 | 22,000 |
| Comparative Example 4 | 18,300 |
| Comparative Example 5 | 16,400 |

Referring to Table 3, the compositions to remove edge beads from the metal-containing resist according to Examples have a superior metal removal effect compared to the compositions to remove edge beads from the metal-containing resist according to Comparative Examples, thereby further promoting the reduction of residual metal.

### Evaluation 2: ArF Pattern Evaluation

The prepared organic metal-containing photoresist (PR) composition was spin-coated on an 8-inch wafer at 1,500 rpm for 30 seconds and then, heat-treated at 110° C. for 60 seconds to manufacture a coated wafer.

The coated wafer was exposed to a 20 mJ to 35 mJ with a L/S pattern by using an ArF immersion exposure apparatus (Nikon Precision Inc.; NSR-S610C, NA=1.30, 0.98/0.65, 35° dipole s-polarized illumination, 6% halftone phase shift mask), baked (PEB) at 100° C. for 60 seconds, developed by utilizing each of the developer compositions according to Examples 7 to 12 and Comparative Examples 6 to 10 at a spin speed of 1500 rpm for 30 seconds, and cured at 240° C. for 60 seconds, obtaining a 1:1 line and space (US) pattern with a width of 40 nm. This pattern was examined with respect to a cross-section shape by using an electron microscope. A pattern collapse occurrence rate of the pattern was calculated according to Equation 1 to evaluate ArF pattern performance. The results are shown in Table 4.

$$Pattern collapse occurrence rate = {\{ ( number of collapsed patterns ) / ( total number of patterns ) \}}^{*} 100 ( \% ) \qquad Equation 1$$

### Evaluation Criteria

∘: pattern collapse occurrence rate<60%
X: pattern collapse occurrence rate≥60%

TABLE 4

| | ArF pattern evaluation |
|---|---|
| Example 7 | ◯ |
| Example 8 | ◯ |
| Example 9 | ◯ |
| Example 10 | ◯ |
| Example 11 | ◯ |
| Comparative Example 6 | X |
| Comparative Example 7 | X |
| Comparative Example 8 | X |
| Comparative Example 9 | X |
| Comparative Example 10 | X |

Referring to Table 4, when applying the metal-containing photoresist developer composition according to the examples, the resolution is excellent or suitable and pattern collapse is minimized or reduced compared to when applying the metal-containing photoresist developer composition according to the comparative examples.

Hereinbefore, certain embodiments of the present disclosure have been described and illustrated, however, it should be apparent to a person having ordinary skill in the art that the present disclosure is not limited to the embodiments as described herein and may be suitably modified and transformed without departing from the spirit and scope of the present disclosure. Accordingly, the modified or transformed embodiments as such may not be understood separately from the technical ideas and aspects of embodiments of the present disclosure, and the modified embodiments may be within the scope of the appended claims and equivalents thereof of the present disclosure.

Reference Numerals

| | |
|---|---|
| 1: substrate support portion | 2: spray nozzle |
| 10: photoresist solution | 12: edge bead |
| 100: substrate | OP: opening |
| 110: feature layer | |
| 110P: feature pattern | 130P: photoresist |

What is claimed is:

1. A composition, comprising:
a cyclic compound comprising at least one heteroatom selected from among N, O, and S in a ring and at least two carbonyl groups; and a solvent,
wherein the composition is a composition to remove edge beads from a metal-containing resist or a developer composition of a metal-containing resist.

2. The composition as claimed in claim 1, wherein:
the cyclic compound is represented by any one selected from among Chemical Formula 1 to Chemical Formula 3: 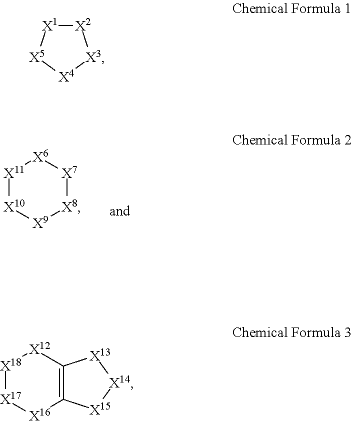
wherein, in Chemical Formula 1 to Chemical Formula 3,
X¹ to X¹⁸ are each independently a carbonyl group (C═(O)), CR¹R², NR³, O, or S,
at least one selected from among X¹ to X⁵ is NR³, O, or S, and at least two are carbonyl groups,
at least one selected from among X⁶ to X¹¹ is NR³, O, or S, and at least two are carbonyl groups,
at least one selected from among X¹² to X¹⁸ is NR³, O, or S, and at least two are carbonyl groups, and
R¹ to R³ are each independently hydrogen, a hydroxyl group, a substituted or unsubstituted C1 to C10 alkyl group, or a combination thereof.

3. The composition as claimed in claim 2, wherein:
Chemical Formula 1 is represented by Chemical Formula 1-1: 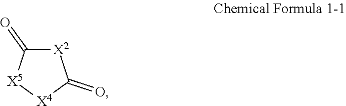
wherein, in Chemical Formula 1-1,
X², X⁴, and X⁵ are each independently CR¹R², NR³, O, or S,
at least one selected from among X², X⁴, and X⁵ is NR³, O, or S, and
R¹ to R³ are each independently hydrogen, a hydroxyl group, a substituted or unsubstituted C1 to C10 alkyl group, or a combination thereof.

4. The composition as claimed in claim 2, wherein:
Chemical Formula 2 is represented by any one selected from among Chemical Formula 2-1 to Chemical Formula 2-3: 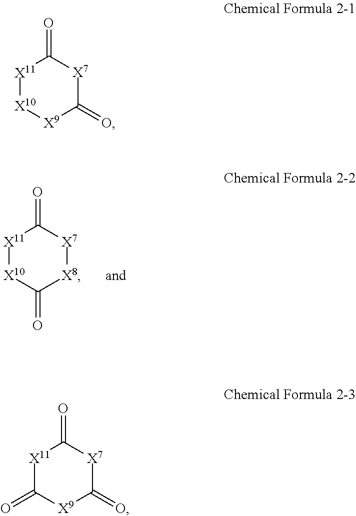
wherein, in Chemical Formula 2-1,
X⁷, X⁹, X¹⁰, and X¹¹ are each independently CR¹R², NR³, O, or S,
at least one selected from among X⁷, X⁹, X¹⁰, and X¹¹ is NR³, O, or S, and
R¹ to R³ are each independently hydrogen, a hydroxyl group, a substituted or unsubstituted C1 to C10 alkyl group, or a combination thereof;
wherein, in Chemical Formula 2-2,
X⁷, X⁸, X¹⁰, and X¹¹ are each independently CR¹R², NR³, O, or S,
at least one selected from among X⁷, X⁸, X¹⁰, and X¹¹ is NR³, O, or S, and
R¹ to R³ are each independently hydrogen, a hydroxyl group, a substituted or unsubstituted C1 to C10 alkyl group, or a combination thereof;
wherein, in Chemical Formula 2-3,
X⁷, X⁹, and X¹¹ are each independently CR¹R², NR³, O, or S,
at least one selected from among X⁷, X⁹, and X¹¹ is NR³, O, or S, and
R¹ to R³ are each independently hydrogen, a hydroxyl group, a substituted or unsubstituted C1 to C10 alkyl group, or a combination thereof.

5. The composition as claimed in claim 2, wherein:
Chemical Formula 3 is represented by any one selected from among Chemical Formula 3-1 to Chemical Formula 3-3: 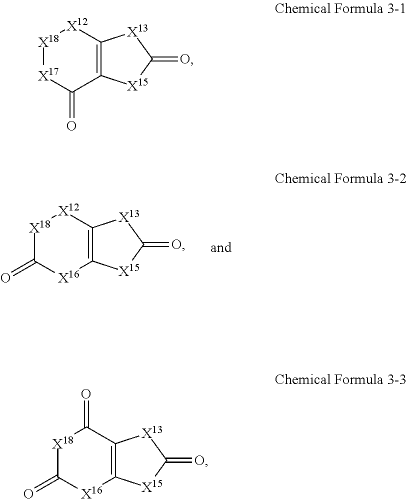
wherein, in Chemical Formula 3-1,
X¹², X¹³, X¹⁵, X¹⁷, and X¹⁸ are each independently CR¹R², NR³, O, or S,
at least one selected from among X¹², X¹³, X¹⁵, X¹⁷, and X¹⁸ is NR³, O, or S,
R¹ to R³ are each independently hydrogen, a hydroxyl group, a substituted or unsubstituted C1 to C10 alkyl group, or a combination thereof;
wherein, in Chemical Formula 3-2,
X¹², X¹³, X¹⁵, X¹⁶, and X¹⁸ are each independently CR¹R², NR³, O, or S,
at least one selected from among X¹², X¹³, X¹⁵, X¹⁶, and X¹⁸ is NR³, O, or S, and
R¹ to R³ are each independently hydrogen, a hydroxyl group, a substituted or unsubstituted C1 to C10 alkyl group, or a combination thereof;
wherein, in Chemical Formula 3-3,
X¹³, X¹⁵, X¹⁶, and X¹⁸ are each independently CR¹R², NR³, O, or S,
at least one selected from among X¹³, X¹⁵, X¹⁶, and X¹⁸ is NR³, O, or S, and
R¹ to R³ are each independently hydrogen, a hydroxyl group, a substituted or unsubstituted C1 to C10 alkyl group, or a combination thereof.

6. The composition as claimed in claim 1, wherein:
the cyclic compound is at least one selected from among the compounds listed in Group 1:

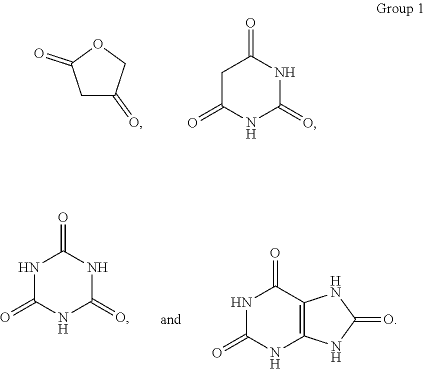 [SMILES: O=C1COC(=O)C1 ; O=C1CC(=O)NC(=O)N1 ; O=c1[nH]c(=O)[nH]c(=O)[nH]1 ; O=c1[nH]c(=O)c2[nH]c(=O)[nH]c2[nH]1]

7. The composition as claimed in claim 1, wherein:
the cyclic compound is in an amount of 0.1 wt % to 50 wt % based on 100 wt % of the composition.

8. The composition as claimed in claim 1, wherein:
a metal compound in the metal-containing resist is an organotin compound comprising at least one selected from an organic oxy group and an organic carbonyloxy group.

9. The composition as claimed in claim 8, wherein:
the metal compound in the metal-containing resist is represented by Chemical Formula 4: 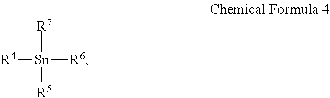
wherein, in Chemical Formula 4,
R⁴ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R⁵ to R⁷ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, an alkoxy or aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h})Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein Rⁱ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R⁵ to R⁷ is selected from an alkoxy or aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h})Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{j}, wherein Rⁱ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

10. The composition as claimed in claim 8, wherein:
the metal compound in the metal-containing resist is represented by Chemical Formula 5 or Chemical Formula 6: 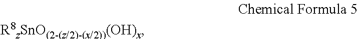
wherein, in Chemical Formula 5,
R⁸ is a C1 to C31 hydrocarbyl group, 0<z≤2, and 0<(z+x)≤4; 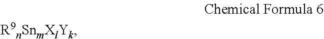
wherein, in Chemical Formula 6,
R⁹ is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur (S), selenium (Se), or tellurium (Te),
Y is —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
n, m, l, and k are each independently an integer of 1 to 20.

11. The composition as claimed in claim 1, further comprising at least one additive selected from among a surfactant, a dispersant, a hygroscopic agent, a coupling agent, and a combination thereof.

12. A method of forming patterns, comprising:
coating a metal-containing resist composition on a substrate;
coating the composition to remove edge beads from the metal-containing resist as claimed in claim 1, along an edge of the substrate;
performing heat treatment to form a metal-containing photoresist film on the substrate by drying and heating;
exposing the metal-containing photoresist film; and
developing.

13. The method as claimed in claim 12, wherein the performing of the heat treatment is performed at a temperature in a range of 80° C. to 120° C.

14. The method as claimed in claim 12, further comprising performing a second heat treatment after the exposing of the metal-containing photoresist film and before the developing, wherein the second heat treatment is performed at a temperature in a range of 90° C. to 200° C.

15. The method as claimed in claim 12, wherein the patterns are a negative-type photoresist pattern.

16. The method as claimed in claim 12, wherein the patterns have a pitch having a half-pitch of less than or equal to 50 nm and a line width roughness of less than or equal to 10 nm.

17. The method as claimed in claim 12, wherein the patterns have a thickness width of 5 nm to 100 nm.

18. The method as claimed in claim 12, wherein the exposing of the metal-containing photoresist film is exposing the metal-containing photoresist film to light having a wavelength range of 5 nm to 150 nm.

19. A method of forming patterns, comprising:
coating a metal-containing resist composition on a substrate;
performing heat treatment to form a metal-containing photoresist film on the substrate by drying and heating;
exposing the metal-containing photoresist film; and
developing utilizing the developer composition of the metal-containing resist as claimed in claim 1.

20. A method of forming patterns, comprising:
coating a metal-containing resist composition on a substrate;
coating the composition to remove edge beads from the metal-containing resist as claimed in claim 1 along an edge of the substrate;
performing heat treatment to form a metal-containing photoresist film on the substrate by drying and heating;
exposing the metal-containing photoresist film; and
developing utilizing the developer composition of the metal-containing resist as claimed in claim 1.
